(19) United States
(12) Patent Application Publication
(10) Pub. No.: US 2004/0203228 A1
(43) Pub. Date: Oct. 14, 2004

(54) METHOD OF FORMING A TUNGSTEN PLUG

(76) Inventors: Ya-Hui Liao, Taipei Hsien (TW); Hung-Chi Pai, Nan-Tou City (TW); Ming-Jui Mao, Tai-Nan City (TW); Shu-En Lee, Hsin-Chu Hsien (TW)

Correspondence Address: NAIPO (NORTH AMERICA INTERNATIONAL PATENT OFFICE), P.O. BOX 506, MERRIFIELD, VA, 22116, US

(21) Appl. No.: 10/249,444

(22) Filed: Apr. 10, 2003

(51) Int. Cl. H01L 21/4763; H01L 21/44

(52) U.S. Cl. 438/644; 438/654

(57) ABSTRACT

A semiconductor wafer including a substrate, a copper dual damascene structure positioned on the substrate, a dielectric layer covering the copper dual damascene structure, and a via hole positioned in the dielectric layer, the hole continuing to a surface of the copper layer. First, a tantalum nitride (TaN) layer is formed on a bottom surface within the via hole and on walls within the via hole. A titanium nitride (TiN) layer is then formed on the tantalum nitride layer. By performing a chemical vapor deposition (CVD) process, a tungsten layer is formed to cover a surface of the titanium nitride layer as well as to fill the via hole. Finally, a chemical mechanical polishing (CMP) process is performed to make a top of the tungsten layer in the via hole aligned with the surface of the dielectric layer so as to form a tungsten plug.

### BACKGROUND OF INVENTION

1. Field of the Invention

The present invention relates to a method of forming a tungsten plug, and more specifically, to a method for preventing copper intrusions of an underlying dual damascene structure of the tungsten plug on a semiconductor wafer.

2. Description of the Prior Art

With the increasing complexity of integrated circuits, the surface of the semiconductor wafer cannot provide enough area to form circuit interconnects. In order to form interconnects on this decreasing MOS transistor scale, a multilevel interconnect process is the typical method used in an integrated circuit. To satisfy the requirements for high integration and high speed in integrated circuits (ICs), especially in a deep sub-micro (<0.18 μm) semiconductor process, a copper (Cu) dual damascene process is becoming more widely used as standard process in forming an interconnection line within the inter-metal dielectric layer of low dielectric constant (low k) materials. Since Copper has both a low resistance and a low electromigration resistance, the low k materials are useful in improving the RC delay effect of a metal interconnection.

In the multilevel interconnect technology; a tungsten (W) plug is widely used in the fabrication of both a contact plug and via plug as it provides for higher integration and better step coverage in a multilevel metallization process. For instance, the tungsten plug is commonly used to electrically connect two conductive layers. Transistors on the wafer connect to each other via the plug so as to form an entire circuit.

The method of forming a tungsten plug according to the prior art starts with forming a barrier layer, normally composed of a titanium/titanium nitride (Ti/TiN) layer, on an inner surface of a via hole or a plug hole, in the dielectric layer. A chemical vapor deposition (CVD) process is then performed fill the via hole or the plug hole with tungsten so as to form the tungsten plug. Copper, having excellent diffusion ability, is employed in the dual damascene structure underlying the bottom end of the tungsten plug, and tantalum nitride (TaN), having excellent adhesion to a tungsten layer formed in subsequent processes, is employed as a barrier layer. By performing a sputtering process, a tungsten film, having a thickness ranging from 300 to 1500 angstroms and favoring the growth of the tungsten layer formed in subsequent processes, is formed on the TaN layer. The tungsten layer, having a thickness ranging from 2500 to 4000 angstroms, is then formed to fill the via hole, or the plug hole, by performing a CVD process. Finally, a chemical mechanical polishing (CMP) process is performed to make a top of the tungsten layer aligned with the surface of the dielectric layer so as to form a tungsten plug.

However, the high temperature in the CVD process employed to form the tungsten layer leads to a thermal stress of portions of copper within the dual damascene structure. The barrier layer, merely composed of TaN, is not able to prevent copper intrusions from the bottom of the plug hole into the plug hole. The resistivity of the tungsten plug is thus increased. Consequently, the electrical performance of the tungsten plug is defected. In addition, a sputtering process is needed to form a tungsten thin film on walls within the plug hole before performing a CVD process to form the tungsten layer. The manufacturing cost according to the prior art is therefore increased.

### SUMMARY OF INVENTION

It is therefore a primary object of the present invention to provide a method of forming a tungsten plug so as to prevent copper intrusions, leading to a defected electrical performance of the tungsten plug, of an underlying dual damascene structure of the tungsten plug on a semiconductor wafer.

According to the claimed invention, a semiconductor wafer comprising a substrate, a copper (Cu) dual damascene structure positioned on the substrate, a dielectric layer covering the copper dual damascene structure, and a via hole positioned in the dielectric layer, the hole continuing to a surface of the copper layer. At the beginning of the method of forming a tungsten plug, a tantalum nitride (TaN) layer, having a thickness ranging from 100 to 1000 angstroms, is formed on a bottom surface within the via hole and on walls within the via hole. A titanium nitride (TiN) layer, having a thickness ranging from 60 to 500 angstroms, is then formed on the tantalum nitride layer by performing a sputtering process or a chemical vapor deposition (CVD) process. A tungsten layer is then formed to cover a surface of the titanium nitride layer as well as to fill the via hole by performing a CVD process. At the end of the method, a chemical mechanical polishing (CMP) process is performed to make a top of the tungsten layer in the via hole aligned with the surface of the dielectric layer so as to form a tungsten plug.

It is an advantage of the present invention against the prior art that a diffusion of Cu from portions of the copper dual damascene structure adjacent to the bottom end of the tungsten plug into the via hole is prevented by the TaN layer and the TiN layer, both employed as barrier layers on the surface of the copper dual damascene structure. In addition, TiN has excellent adhesion to tungsten, so the tungsten layer can be directly deposited on portions of the TiN layer in the via hole 22 by performing a CVD process. The step of sputtering a tungsten thin film on walls within the via hole according to the prior art is thus eliminated.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 to FIG. 4 are schematic views of forming a tungsten plug according to the present invention.

### DETAILED DESCRIPTION

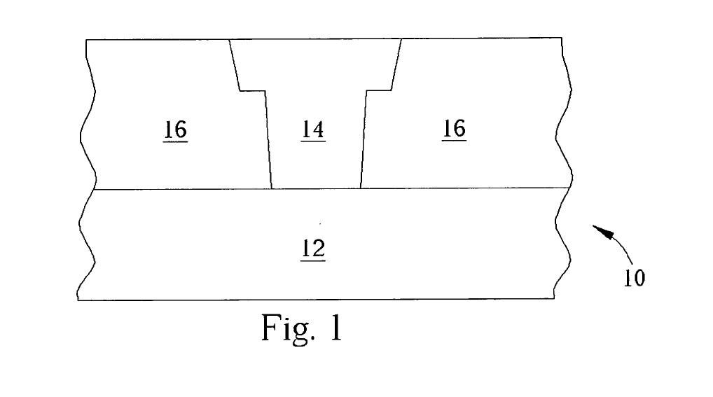

Please refer to FIG. 1 to FIG. 4 of schematic views of forming a tungsten plug 30 according to the present invention. As shown in FIG. 1, a semiconductor wafer 10 comprises a substrate 12 and a copper (Cu) dual damascene structure 14, further comprising a bottom via structure and an upper trench structure and employed as portions of a metal interconnection,formed in a dielectric layer 16.

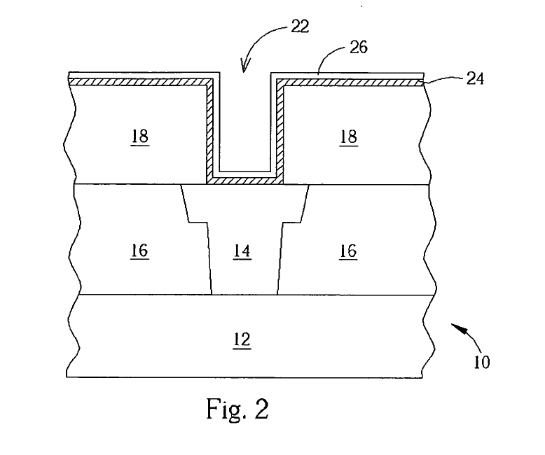

As shown in FIG. 2, a dielectric layer 18, normally composed of silicon oxide, is formed to smoothly cover both a top surface of the dual damascene structure 14 and a surface of the dielectric layer 16. By performing a lithography process and a dry etching process, a via hole 22 is formed in portions of the dielectric layer 18 on the top surface of the dual damascene structure 14 so that a tungsten plug 30 (not shown) formed in subsequent processes can be employed as the interconnection electrically connecting an upper metal wire (not shown) to the copper dual damascene structure 14. A tantalum nitride (TaN) layer 24, having a thickness ranging from 100 to 1000 angstroms,is then formed on a bottom surface within the via hole 22 and on walls within the via hole 22, as well as to cover the dielectric layer 18. The TaN layer 24 is used as a barrier layer and can improve the adhesion of the tungsten plug 30 to the dielectric layer 18 in subsequent processes. By performing a sputtering process or a chemical vapor deposition (CVD) process, a titanium nitride (TiN) layer 26, having a thickness ranging from 50 to 600 angstroms and employed as a barrier layer as well, is formed on the TaN layer 24.

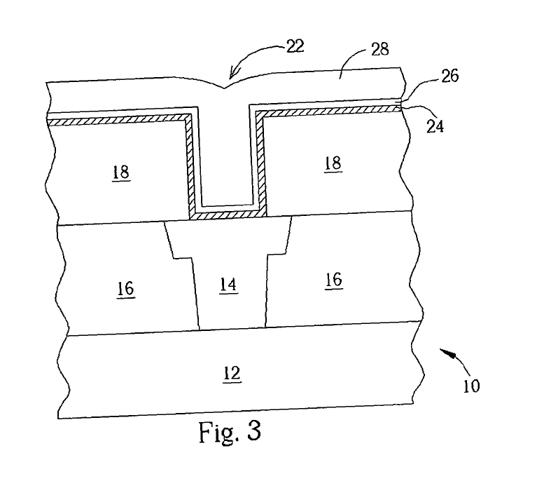

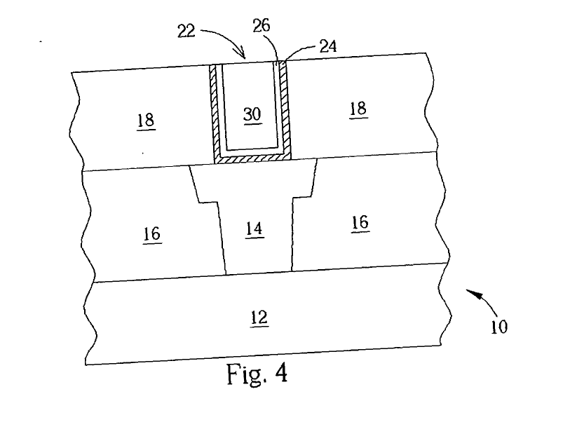

As shown in FIG. 3, by performing a CVD process, a tungsten layer 28 is formed to cover a surface of the titanium nitride layer 26 and to fill the via hole 22. As shown in FIG. 4, a chemical mechanical polishing (CMP) process is performed to make a top of portions of the tungsten layer 28 in the via hole aligned with the surface of the dielectric layer 18 so as to form a tungsten plug at the end of the method.

To prevent a diffusion of Cu from portions of the copper dual damascene structure 14 adjacent to the bottom end of the tungsten plug 30 into the via hole 22, a combination of the TaN layer 24 and the TiN layer 26 is employed as a barrier layer on the surface of the copper dual damascene structure 14. Commonly, a barrier layer comprises the following properties: (1) good exclusion of the diffusing atoms, (2) good adhesion to Cu and the dielectric layer, and (3) proper resistance (<1000 μΩ-cm). In comparison with the prior art, the TaN layer 24 and the TiN layer 26, both used as barrier layers, are formed atop the copper dual damascene structure 14 before the tungsten layer 28 is formed by performing a CVD process. Copper intrusions of the copper dual damascene structure 14 caused by the high operating temperature of the CVD process are thus prevented by the barrier layer, composed of the TaN layer 24 and the TiN layer 26 and having a better performance than the barrier merely composed of TaN in the prior art. In addition, TiN has excellent adhesion to tungsten, so the tungsten layer 28 can be directly deposited on portions of the TiN layer 26 in the via hole 22 by performing a CVD process. The step of sputtering a tungsten thin film on walls within the via hole according to the prior art is thus eliminated. Additionally, processes for depositing TaN and that for depositing TiN layer 26 can be performed by utilizing a same sputtering machine. The manufacturing processes are therefore improved in the present invention.

Those skilled in the art will readily observe that numerous modifications and alterations of the device may be made while retaining the teachings of the invention. Accordingly, the above disclosure should be construed as limited only by the metes and bound of the appended claims.

1. A method of forming a tungsten (W) plug on a semiconductor wafer, the semiconductor wafer comprising a substrate, a copper (Cu) layer positioned on the substrate, a dielectric layer positioned on the copper layer, and a via hole positioned in the dielectric layer, the hole continuing through to a surface of the copper layer, the method comprising:
forming a tantalum nitride (TaN) layer on a bottom surface within the via hole and on walls within the via hole;
forming a titanium nitride (TiN) layer on the tantalum nitride layer; and
performing a chemical vapor deposition process to form a tungsten layer on the a surface of the titanium nitride layer so as to form the tungsten plug in the via hole, the TaN layer and the TiN layer used to prevent a diffusion of Cu from the Cu layer adjacent to a bottom end of the tungsten plug into the via hole.

2. The method of claim 1 wherein the titanium nitride layer is formed by a sputter process, or by a chemical vapor deposition process.

3. The method of claim 1 wherein the titanium nitride layer has a thickness of about 50 to 600 angstroms.

4. The method of claim 1 wherein the tantalum nitride layer has a thickness of about 100 to 1000 angstroms.

5. The method of claim 1 wherein the method further comprises performing a chemical mechanical polishing (CMP) process after performing the chemical vapor deposition process.

6-11. (Canceled)
